(19) United States
(12) Patent Application Publication
(10) Pub. No.: US 2026/0367657 A1
(43) Pub. Date: Nov. 19, 2026

(54) ADAPTIVE VOLTAGE CONVERTER WITH TUNABLE PIECEWISE LINEAR OUTPUT

(71) Applicant: Ambiq Micro, Inc., Austin, TX (US)

(72) Inventors: Scott Hanson, Austin, TX (US); Daniel Cermak, Austin, TX (US); Anshuman Singh, Austin, TX (US); Ivan Bogue, Austin, TX (US); Ivan Viktorovich Kochkin, Austin, TX (US)

(21) Appl. No.: 19/210,314

(22) Filed: May 16, 2025

(51) Int. Cl. G05F 1/567; H03K 17/687

(52) U.S. Cl. CPC G05F 1/567; H03K 17/687

(57) ABSTRACT

An adaptive voltage converter outputting a regulated voltage according to a piecewise linear regulated voltage curve having a complementary-to-absolute-temperature section and a saturation voltage section is disclosed. A voltage output circuit outputs a regulated voltage. A voltage reference generator is coupled to the voltage output circuit. A voltage divider circuit is coupled to the voltage output circuit. At least one of the voltage reference generator or voltage divider circuit outputs a tuned voltage reference signal to the voltage output circuit to output the regulated voltage on a piecewise linear (PWL) curve based on tuning of at least one of a saturation temperature or a saturation voltage.

### TECHNICAL FIELD

The present invention relates generally to voltage converters. More specifically, an adaptive voltage converter that generates a tunable sub-threshold or near-threshold output voltage according to a piecewise linear curve having a complementary-to-absolute temperature (CTAT) characteristic and a saturation voltage with a zero temperature coefficient is disclosed.

### BACKGROUND

Circuits adapted to operate in a sub-threshold domain of transistors have been disclosed. Sub-threshold circuits operate at a supply voltage (“VDD”) that is below the transistor threshold voltage (Vth). Perhaps the single greatest challenge of operating circuits in the sub-threshold domain is the exponential sensitivity of circuit parameters to manufacturing process variations and operating temperature. Even circuits that operate at near-threshold supply voltages experience near-exponential sensitivity to temperature and process. For the purposes of this description, near-threshold voltages shall be defined as comprising substantially the near-exponential region between about VDD=Vth and about VDD=Vth+0.4 volts. These exponential sensitivities result in switching speed and power fluctuations that are intolerable in most applications. It is therefore desirable to adapt a voltage converter circuit under changing process and temperature conditions to maintain constant or near-constant performance and power.

As is known, the tuning of the voltage level with respect to temperature must be carried out differently in sub-threshold and near-threshold than in super-threshold. Super-threshold circuits have a relatively low sensitivity to temperature and process variations, and tend to operate more slowly at higher temperatures. In contrast, sub-threshold circuits have exponential sensitivities to temperature and process, and actually operate faster at higher temperatures. Consequently, to maintain constant performance in a sub-threshold or near-threshold circuit across temperature, supply voltage must increase as temperature falls and decrease as temperature increases. Such a characteristic, which may or may not be substantially linear, is typically called complementary-to-absolute-temperature (“CTAT”). While a CTAT voltage characteristic is advantageous in the sub-threshold and near-threshold regions, it can cause voltage to drop below a desired minimum operating voltage. It is thus preferable to maintain any CTAT voltage above a saturation voltage level, which is achieved at a saturation temperature.

Adjusting the supply voltage (“VDD”) is considered to be one of the best techniques for adapting power and performance under changing process and temperature. In sub-threshold circuits, circuit speed changes exponentially with VDD. Most circuits already have integrated voltage conversion circuitry, and this circuitry can be converted to an adaptive supply with only minimal overhead. However, what is needed is an adaptive voltage converter designed specifically to compensate for the exponential sensitivities of sub-threshold and near-threshold circuits.

Another important challenge in sub-threshold and near-threshold circuits is the extreme disparity between the power/performance requirements when a system is in an active mode and the power/performance requirements when a system is in a sleep mode. Voltage regulators are among the most important circuit blocks in a sub-threshold or near-threshold chip, and it is extremely challenging to design a single voltage converter that can simultaneously meet the bandwidth requirements of active mode and the ultra-low quiescent current requirements of sleep mode. In light of this, it is desirable to create a voltage converter that can adapt as the system moves from active mode to sleep mode.

There is a need for an adaptive voltage converter that allows tuning of saturation temperature and saturation voltage in a piecewise linear voltage output curve. There is a further need for tunability of a slope of the complementary-to-absolute-temperature section of the curve. There is also a need for an adaptive voltage converter that can change its power/performance characteristics between different energy modes.

### SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, an adaptive voltage converter is disclosed. The voltage converter includes a voltage output circuit outputting a regulated voltage and a voltage divider circuit coupled to the voltage output circuit. A voltage reference generator is coupled to the voltage output circuit. At least one of the voltage reference generator or the voltage divider circuit output a tuned voltage reference signal to the voltage output circuit to output the regulated voltage on a piecewise linear (PWL) curve based on tuning of at least one of a saturation temperature or a saturation voltage.

A further implementation of the example voltage converter includes a voltage controller coupled to the voltage reference generator and the voltage divider circuit. The voltage controller controls the voltage reference generator or the voltage divider to output the tuned voltage reference signal to the voltage output circuit. Another implementation is where the voltage controller outputs a first tuning signal to the reference voltage generator or the voltage divider circuit to set the saturation temperature and a second tuning signal to the reference voltage generator or the voltage divider circuit to set the saturation voltage. Another implementation is where the voltage controller is an integrated circuit having trim value outputs for tuning the saturation temperature and saturation voltage. Another implementation is where the voltage controller is operable to control the voltage reference generator or the voltage divider circuit to tune a slope of a complementary temperature (CTAT) section of the PWL curve. Another implementation is where the voltage output circuit is one of a linear regulator or a switching converter. Another implementation is where the tuning incorporates a process corner of an integrated circuit. Another implementation is where the voltage reference generator includes a temperature dependent adjustment circuit that adjusts the reference voltage based on temperature. Another implementation is where the example voltage converter includes a temperature sensor coupled to logic to adjust a reference voltage based on sensed temperature. Another implementation is where the regulated voltage is a selected one of a sub-threshold voltage less than a threshold voltage of a transistor (Vdd<Vth) of an integrated circuit and a near-threshold voltage greater than or equal to the threshold voltage of the transistor and less than or equal to 0.4 volts above the threshold of the transistor (Vth≤Vdd≤(Vth+0.4 volts)). Another implementation is where the voltage reference generator includes a circuit to tune the saturation temperature and the saturation voltage. Another implementation is where the voltage divider circuit includes a piecewise linear current source.

Another disclosed example is a method of tuning an adaptive voltage converter including a voltage output circuit outputting a voltage according to a piecewise linear regulated voltage curve having a complementary-to-absolute-temperature section and a saturation voltage section. A saturation voltage of the piecewise linear regulated voltage curve is determined. A saturation temperature for the piecewise linear regulated voltage curve is determined. At least one of a voltage reference generator or a voltage divider is tuned to output a reference voltage to the voltage output circuit according to one of the determined saturation voltage or saturation temperature.

A further implementation of the example method includes a voltage controller coupled to the voltage reference generator and the voltage divider circuit controlling the voltage reference generator or the voltage divider to output the tuned voltage reference signal to the voltage output circuit. Another implementation is where the voltage controller is an integrated circuit having trim value outputs for tuning the saturation temperature and saturation voltage. Another implementation is where the method includes controlling the voltage reference generator or the voltage divider circuit to tune a slope of a complementary temperature (CTAT) section of the PWL curve. Another implementation is where the tuning incorporates a process corner of an integrated circuit. Another implementation is where the voltage reference generator includes a temperature dependent adjustment circuit that adjusts the reference voltage based on temperature. Another implementation is where the regulated voltage is a selected one of a sub-threshold voltage less than a threshold voltage of a transistor (Vdd<Vth) of an integrated circuit and a near-threshold voltage greater than or equal to the threshold voltage of the transistor and less than or equal to 0.4 volts above the threshold of the transistor (Vth≤Vdd≤(Vth+0.4 volts)).

Another disclosed example is a non-transitory computer readable medium including executable instructions which, when executed in a processor causes the processor to determine a saturation voltage of a piecewise linear regulated voltage curve having a complementary-to-absolute-temperature section and a saturation voltage section. The instructions cause the processor to determine a saturation temperature for the piecewise linear regulated voltage curve. The instructions cause the processor to tune at least one of a voltage reference generator or a voltage divider to output a reference voltage to a voltage output circuit according to one of the determined saturation voltage or saturation temperature

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure will be better understood from the following description of exemplary embodiments together with reference to the accompanying drawings, in which:

FIG. 1 is a diagram of a system on chip in an energy efficient device requiring near threshold voltages for various components;

FIG. 2 is a block diagram of the example system on chip in FIG. 1;

FIG. 3 is a block diagram of an example adaptive voltage converter that provides a piecewise linear output voltage for the system on chip in FIG. 2;

FIG. 4 is a block diagram of the reference voltage generator of the adaptive voltage converter in FIG. 3;

FIG. 5 is a detailed block diagram of the buck converter of the example adaptive voltage converter;

FIG. 6 is a block diagram of another adaptive voltage converter that uses a voltage divider circuit and a current reference to tune a piecewise linear output voltage; and

FIG. 7 is a block diagram of an example piecewise linear current source for the adaptive voltage converter in FIG. 3.

FIG. 8A is a graph of an ideal piece-wise linear (PWL) output voltage curve;

FIG. 8B is a graph showing the effects of tunning the example adaptive voltage converter to change parameters of the PWL output voltage curve; and

FIG. 9 is an example weighted transistor circuit that may be used for fine tuning of parameters of the PWL output voltage curve for the example adaptive voltage converters.

The present disclosure is susceptible to various modifications and alternative forms. Some representative embodiments have been shown by way of example in the drawings and will be described in detail herein. It should be understood, however, that the invention is not intended to be limited to the particular forms disclosed. Rather, the disclosure is to cover all modifications, equivalents, and alternatives falling within the spirit and scope of the invention as defined by the appended claims.

### DETAILED DESCRIPTION

The present inventions can be embodied in many different forms. Representative embodiments are shown in the drawings, and will herein be described in detail. The present disclosure is an example or illustration of the principles of the present disclosure, and is not intended to limit the broad aspects of the disclosure to the embodiments illustrated. To that extent, elements, and limitations that are disclosed, for example, in the Abstract, Summary, and Detailed Description sections, but not explicitly set forth in the claims, should not be incorporated into the claims, singly, or collectively, by implication, inference, or otherwise. For purposes of the present detailed description, unless specifically disclaimed, the singular includes the plural and vice versa; and the word “including” means “including without limitation.” Moreover, words of approximation, such as “about,” “almost,” “substantially,” “approximately,” and the like, can be used herein to mean “at,” “near,” or “nearly at,” or “within 3-5% of,” or “within acceptable manufacturing tolerances,” or any logical combination thereof, for example.

The present disclosure is directed toward an adaptive voltage converter with a complementary-to-absolute temperature (CTAT) characteristic and a saturation voltage according to a piecewise linear (PWL) voltage output curve. The regulated voltage output of the example voltage converter (Vsub or Vnear) is controlled to have approximately zero temperature coefficient (ZTC) above a saturation temperature (TSAT) while still maintaining CTAT behavior below the saturation temperature. The resulting temperature characteristic is a piecewise linear characteristic that ensures that the regulated voltage stays at or near a critical saturation voltage (VDDSAT). This allows the voltage converter to generate a sub-threshold or near-threshold voltage for specific loads while keeping VDD at a safe operating level. This can be useful in providing voltage to SRAM circuits, for example, in which functionality can be compromised at extremely low values. The example adaptive voltage converter allows a minimal voltage to be tuned that prevents falling below the critical saturation voltage.

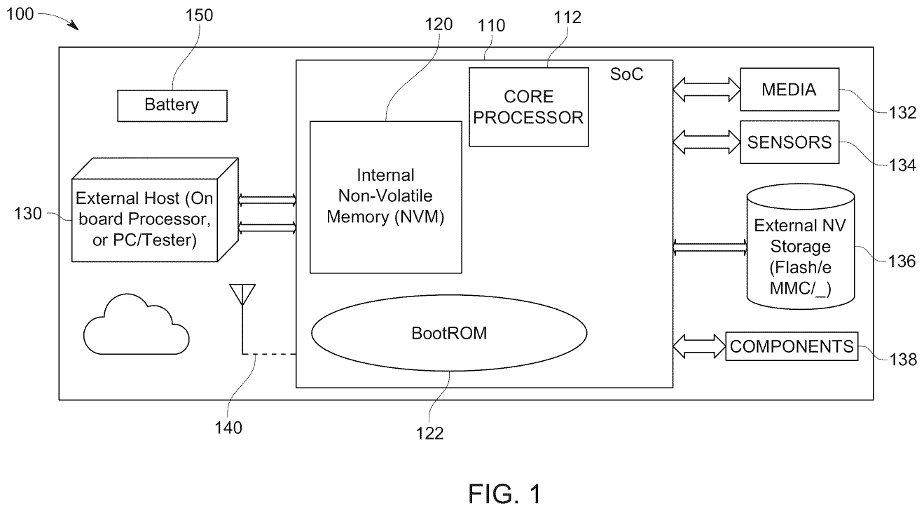

FIG. 1 shows a block diagram of a device 100 with a system on chip 110. The system on chip 110 includes a core processor 112 and non-volatile memory 120 that is a magneto-resistive RAM (MRAM). The system on chip 110 also includes permanent memories such as a read only secure boot read only memory (ROM) 122. In this example, the system on chip 110 is installed in the device 100 and the core processor 112 executes applications generally stored in the non-volatile memory 120 to operate the device 100 to perform different functions.

The device 100 may include an external host processor 130 that controls the functions of the system on chip 110, which may be connected via wired interfaces such as UART, SPI, or I2C interfaces. The system on chip 110 controls and accesses a set of components on the device 100 that may include media devices 132 such as a display or an audio output, sensors 134, a non-volatile (NV) memory device 136 such as MSPI Flash or eMMC, or other components 138. As will be explained the NV memory device 136 serves as an alternate storage device for storing a recovery image. The host processor 130 could be coupled to a wireless interface 140 such as Bluetooth or Wi-Fi that allows communication with external components to the device 100. A battery 150 provides power to the components of the device 100 including the system on chip 110.

Although not all of the electronic components illustrated in FIG. 1 may be operable in the sub-threshold or near-threshold domains in any particular embodiment, some, at least, may be advantageously adapted to do so, with concomitant reductions in system power dissipation.

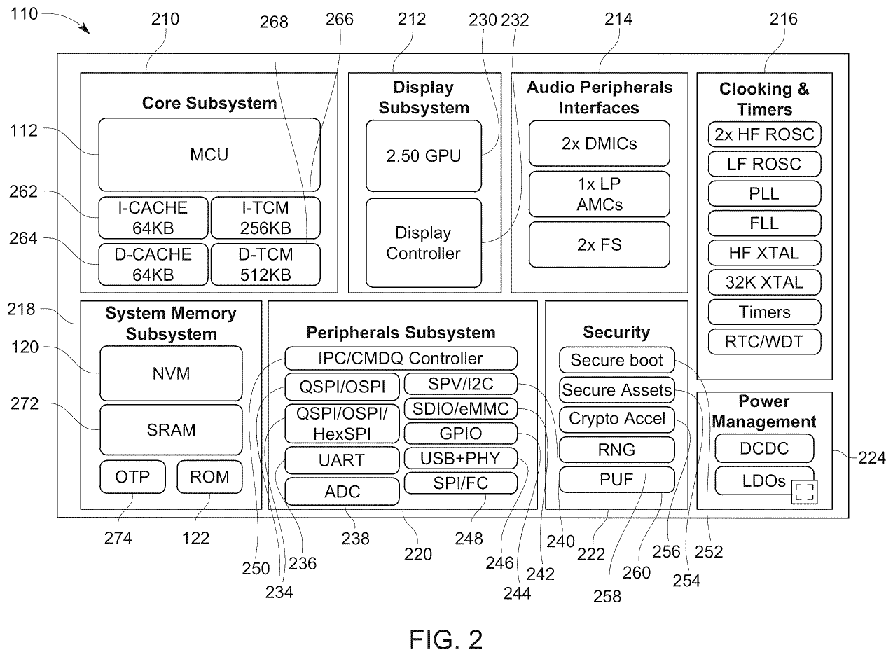

FIG. 2 shows a block diagram of the system on chip 110 in FIG. 1. The system on chip 110 includes a core subsystem 210, a display subsystem 212, an audio peripherals subsystem 214, a clock and timers subsystem 216, a memory subsystem 218, a peripheral subsystem 220, a security subsystem 222, and a power management subsystem 224. The display subsystem 212 includes a graphic processor 230 and a display controller 232 to drive displays on the device 100. The audio peripherals subsystem 214 includes different audio peripheral interfaces for driving audio components on the device 100. The clock and timers subsystem 216 includes timers and clocks for the system on chip 110.

The peripheral subsystem 220 includes different interfaces such as QSPI/OSPI/HexSPI interfaces 234, UART interfaces 236, analog to digital converters 238, SP/I2C master interfaces 240, SDIO (Secure Digital Input Output)/MMC (Multi-Media card) interfaces 242, a set of general purpose input/output (GPIO) pins 244, a USB interface 246, and a SPI slave interface 248. The peripheral interfaces are managed by a peripheral controller 250 that manages inter process communication (IPC) and a command queue (CMDQ). The security subsystem 222 includes a secure boot 252, security assets 254, a crypto accelerator 256, a random number generator (RNG) 258 and a physical unclonable function (PUF) 260. The power management subsystem 224 includes power sources such low drop out (LDO) regulators, buck converters, and other voltage regulator supply sources.

The core subsystem 210 includes the core processor 112 that may be any suitable processor, microcontroller, and the like. In this example, the core processor 112 is an ARM Cortex MCU, but any suitable programmable controller or processor may be used. The core subsystem 210 includes an instruction cache 262 and a data cache 264. The core subsystem 210 includes an instruction tightly controlled memory (TCM) 266 and a data TCM 268. The memory subsystem 218 includes synchronous static random access memory (SSRAM) 272, a one-time programmable (OTP) device 274, and the read only memory (ROM) 122. In this example, the OTP device 274 is an e-fuse. The OTP device 274 stores data such as trim values that may written during production testing and is read by the core processor 112 for tuning components such as the example adaptive voltage converter. The memory subsystem 218 also includes the non-volatile memory 120, which is MRAM in this example.

The power management subsystem 224 includes the example adaptive voltage converter. The power management subsystem 224 provides voltage to both digital modules such as the core subsystem 210 and analog modules such as the clocking and timers subsystem 216 and analog to digital converters (“ADC”) in the peripheral subsystem 220, and the like. The power management subsystem 224 includes reference voltage generators and reference current generators. The reference voltage generator and reference current generator are each common modules for supplying a stable reference signal to analog modules on the chip 110. The reference voltage generator is sometimes used to derive the output reference current provided by reference current generator. As will be explained, either the reference voltage generator or the reference current generator may be used by an adaptive voltage converter to generate a PWL voltage output.

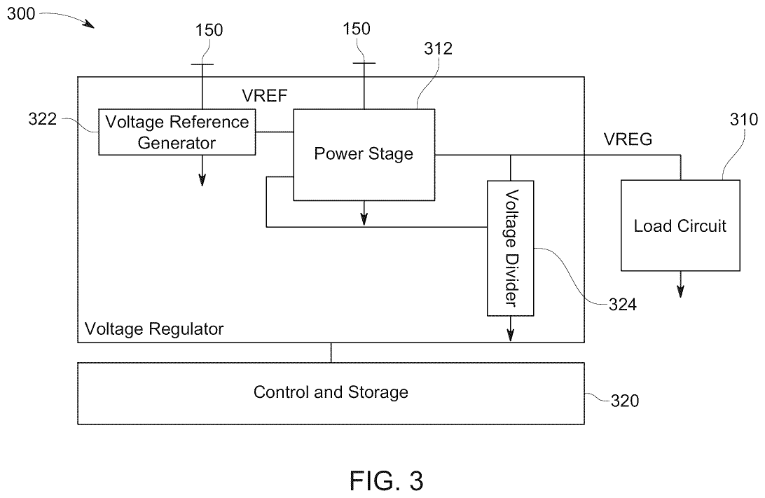

FIG. 3 shows a block diagram of an example voltage converter 300. In general, the voltage converter 300 is adapted to deliver to a load, e.g., any of the several components in the system 110 in FIG. 2, a regulated voltage that is dynamically adjusted as a function complementary to absolute temperature. As will be explained the example voltage converter 300 outputs voltage according to a piecewise linear curve. The parameters of the output voltage curve may be tuned for different requirements such as subthreshold or near subthreshold voltage levels.

The battery 150 supplies a voltage, VBat, to the example voltage converter 300, which generates a lower regulated voltage, VReg, that may be delivered to a load circuit 310, which can be a circuit of any type such as the SSRAM 272, or other components in FIG. 2. The voltage VReg may be at a sub-threshold, a near-threshold or a super-threshold level for transistors of the circuit. In this example, the voltage converter 300 may comprise a voltage output circuit that may be switching converters such as a buck converter 312 or a voltage regulator such as linear voltage regulator.

A voltage controller 320 controls the value of the output voltage and also tunes the outputs. The controller 320 may be a specific set of hardware circuits to perform the operations described herein. Alternatively, the controller 320 may be software running on a general processor, a specialized controller such as an application specific integrated circuit (ASIC), or a hardware programmed device such as a field programmable gate array (FPGA) or a complex programmable logic device (CPLD). The controller 320 controls the output of a voltage reference (VRef) generator 322 that supplies a reference voltage to the voltage output circuit 312. The regulated voltage output may be fed back through a voltage divider 324 to the voltage output circuit 312 to compare against VRef and assist in regulating the voltage level. In addition to basic voltage regulation, the voltage converter 300 may be adapted to change the output of the voltage output circuit 312 based on a number of variables, including, for example, process corners, temperature, and system operating mode. The controller 320 may trim the outputs through stored trim values.

As has been noted, the example voltage converter 300 includes the buck converter 312 for high-efficiency conversion during an active mode. Alternatively, a linear voltage regulator may be included for ultra-low quiescent current operation during a sleep mode. In such a configuration with two voltage circuits, if one of the voltage converters is in use, it would be typical to power down the other unused voltage circuit to save energy. The buck converter 312 is capable of delivering power at a variety of voltages (including sub-threshold and near-threshold voltages) with power efficiencies exceeding 90%. However, load currents in a sub-threshold or near-threshold circuit may fall below 100 nA in a sleep mode, and the power efficiency of buck converter 312 could easily fall below 5%. In this sleep mode, it may be desirable to switch over to a second converter that offers better power efficiency. For example, a linear voltage regulator can be easily adapted to operate with quiescent current on the order of 1 nA yet be capable of delivering much great power efficiency with load currents on the order of 100 nA. Typically, such a linear regulator will be incapable of sourcing active load currents in the range of 100 μA to 5 mA, but automatic switchover to the buck converter in active mode solves this problem.

It is common for microcontrollers (“MCUs”) such as the MCU 112 to have architected power states (e.g., an active state, a sleep state, a deep sleep state, etc.). Typically, such an MCU will have a power management unit (“PMU”) that is responsible for switching between architected power states. Since the PMU is driving transitions between power states, it may also be used as the controller 320 in FIG. 3 to drive transitions between voltage levels in the voltage converter 300.

As previously mentioned, an adaptive voltage supply is one of the best available tools to manage the exponential sensitivities of sub-threshold and near-threshold circuits. In one embodiment of the adaptive voltage converter 300, the VReg voltage level is adjusted in response to different manufacturing process variations or environmental conditions. The tuning of the voltage level can be software controlled or can be controlled by a control circuit in a closed-loop fashion. The voltage level output by the voltage output circuit 312 can be controlled by changing the reference voltage, the voltage divider 324, or any other available tuning parameter with respect to temperature and/or process.

As will be explained below, in one example, the VRef voltage output by the reference voltage generator 322 is dynamically adjusted in a closed loop fashion via self-adapting circuitry or by the controller 320 as a function of complementary to absolute temperature and at a saturation voltage for temperatures higher than a saturation temperature. Although the generation of such a function can be achieved in an open-loop manner with software that periodically measures temperature with a sensor (not shown), it may be desirable to construct a closed-loop circuit that requires no software intervention.

For example, a circuit based on a two-transistor based sub-threshold reference voltage generator circuit can be easily adapted to adjust the VRef voltage (and subsequently the VReg voltage) to exhibit PWL behavior. Several examples of such two-transistor based reference voltage generator circuits may be found in FIG. 2 (reference voltage generators 12A, 12B, and 12C) of U.S. Pat. No. 10,013,006 and the associated descriptions. That patent is hereby incorporated by reference.

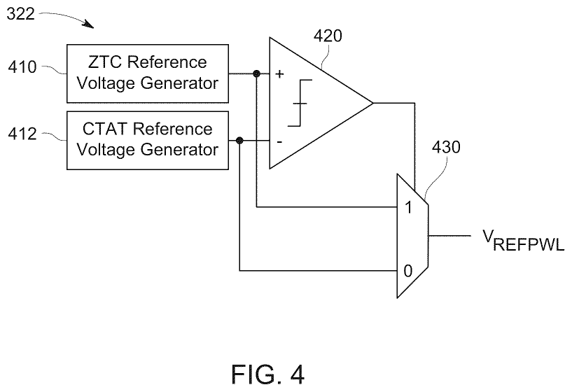

The reference voltage generator 322 in this example is implemented as a PWL reference voltage generator as shown in FIG. 4. The reference voltage generator 322 includes a zero temperature coefficient (ZTC) reference voltage generator 410 and a CTAT reference voltage generator 412. Both the ZTC reference voltage generator 410 and the CTAT reference voltage generator 412 may use the two transistor design discussed above in U.S. Pat. No. 10,013,006. The outputs for the voltage generators 410 and 412 are coupled to the respective positive and negative inputs of a comparator 420. The output of the comparator 420 is coupled to a select input of a multiplexer 430. The inputs of the multiplexer are tied to the outputs of the voltage generators 410 and 412.

The first reference voltage generator 410 provides a voltage with zero temperature coefficient (i.e., it is substantially constant across temperature), and the second reference voltage generator 412 provides a CTAT voltage. In this example, both the ZTC reference voltage generator 410 and CTAT reference voltage generator 412 may use the two transistor design discussed above. As described in U.S. Pat. No. 10,013,006, the temperature coefficient of a two transistor reference voltage generator can be changed from proportional-to-absolute-temperature (PTAT) to ZTC to CTAT by changing the relative sizes of the two transistors. This can be done with fixed sizes or can be achieved by dynamically changing the size of transistors based on specific chip needs. The output of the comparator 420 is coupled to the multiplexer 430 which selects either the first reference voltage generator output or the second reference voltage generator output. Such a circuit, used as a basis of the reference voltage generator 322, automatically forces VReg to vary as a function complementary to absolute temperature without software intervention.

The reference voltage generator 322 thus outputs a PWL reference voltage. During the CTAT portion of the curve the reference voltage generated by the reference voltage generator 400 is the output of the CTAT reference voltage generator 412 as selected by the select input to the multiplexer 430. When the output of the CTAT voltage reference generator 412 drops below the output of the ZTC reference voltage generator 410, the output of the comparator 420 switches, causing the multiplexer 430 to select the output of the ZTC reference voltage generator 410. As explained above, the reference voltage generator 322 may be tuned by control signals from the controller 320.

The tuning of the VReg voltage level with respect to variations in the manufacturing process for different components of the system 110 is also important. In general, this tuning step is best done at the time of production testing. Tuning parameters can be stored in an on-board non-volatile memory such as the OTP 274 in FIG. 2 and then can be loaded to the controller 320 upon powering up the system 110 for the first time. For chips with transistors that exhibit slow process characteristics (e.g., high threshold voltage or long gate length), the regulated voltage will generally be adjusted to a higher level to ensure a minimum performance level. Conversely, the regulated voltage will generally be adjusted down to save energy while maintaining performance for chips with faster process characteristics. Any known trimming algorithm may be used for determining the correct voltage level settings.

The above principles describe the adaptation of supply voltage in response to temperature and process fluctuations. However, the supply voltage, VReg can also be adapted to other factors. For example, as the workload of the system 110 changes, VReg can be changed accordingly. The system 110 might remain in a sub-threshold or near-threshold low performance, low energy mode while handling background tasks like sensing and data movement. When handling applications with real-time requirements, the system 110 might automatically increase voltage generated by the voltage converter 300 to a super-threshold voltage level to achieve higher performance at the expense of energy efficiency.

Other reference voltage circuits that generate a reference voltage may also be used. It should be noted that most implementations of a reference voltage generator will not generate a perfect PWL characteristic. The CTAT and ZTC portions of the curve may not be perfectly linear. This is not critical. It is instead important that the curve sections have a substantially linear CTAT and a ZTC that results in a substantially flat saturation voltage.

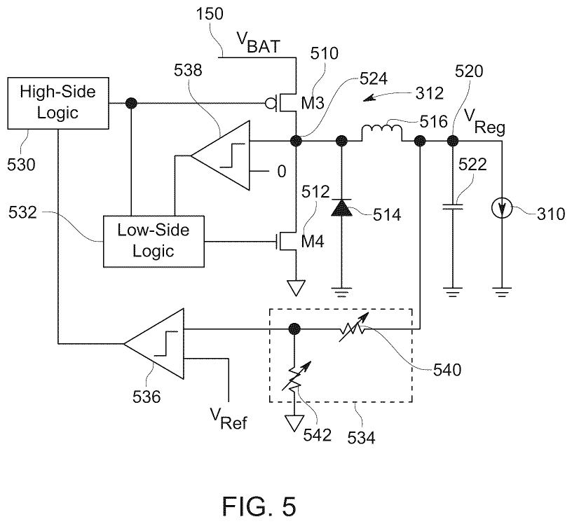

FIG. 5 shows a detailed circuit diagram of the buck converter 312. The buck converter 312 is powered by the battery 150 in FIG. 1, which is coupled to a PMOS transistor 510 in series with an NMOS transistor 512. A node 524 between the transistors 510 and 512 is coupled to a diode 514 and an inductor 516. A regulated voltage output 520 from one end of the inductor 516 is a stepped down voltage from voltage (VBat) from the battery 150. A capacitor 522 smooths the voltage signal from the output 520. In this example, the buck converter 312 may output voltage levels that are controlled by a high side logic 530 and a low side logic 532. An output of a resistive divider circuit 534 is coupled to a comparator 536. In this example, the voltage controller 320 provides the high power (binary 1) signal 344 to the high side logic 530 to turn on the buck converter 312.

The comparator 536 includes an input that is tied to the reference voltage (VRef) generated by the reference voltage generator 322 in FIG. 3 and an input coupled to the output of the resistive divider circuit 534, which is a function of the regulated voltage output (VReg). The comparator 536 includes an output VFB (feedback voltage) that is based on a comparison of VRef to a function of the regulated voltage output (VReg) from the resistive divider circuit 534. Alternatively, a function of VRef may be output by the reference voltage generator 322 as explained herein. The transistors 510 and 512 will then switch on power to the VReg output 520 when indicated by VFB. For purpose of this disclosure “high voltage” or “binary 1” shall be understood to refer to a voltage sufficiently high to turn on an N-type transistor for the implementing process, e.g. the NMOS transistor 512 in the CMOS technology used to implement the buck converter 312. A “low voltage” or “binary 0” is understood to be sufficiently low to turn on a P-type transistor for the implementing process, e.g., the PMOS transistor 510 in the CMOS technology used to implement the buck converter 312.

The high side logic 530 takes as an input VFB generated by the comparator 536 and outputs a signal to the gate of the transistor 510. The low side logic 532 has an input coupled to the output of the high side logic 530 and provides an output to the gate of the NMOS transistor 512. The high and low side logics 530 and 532 switch the NMOS and PMOS transistors 510 and 512 to provide the desired voltage at the output 520 (VReg).

A reactive step-down circuit including the inductor 516, the capacitor 522, and the diode 514 have the illustrated configuration, which is common to most buck converters known in the art. One end of the inductor 516 is coupled to one end of the diode 514 and one end of the capacitor 522. The other end of the inductor 516 is coupled to the regulated voltage output 520 (VREG). The VREG output 520 is coupled to ground by the capacitor 522 and the node 524 between the transistors 510 and 512 is coupled to ground by the diode 514, which is oriented to allow current flow toward the node between the transistors 510 and 512.

When the comparator 536 asserts a signal on the VFB input indicating that the voltage supplied by the VREG output 520 is low, the high side logic 530 asserts a low (e.g., binary 0) voltage on the gate of the transistor 510, which turns on the PMOS transistor 510 allowing current to flow through the inductor 516 thereby powering the reactive step-down circuit.

When the comparator 536 no longer asserts a signal on the VFB input (indicating that the VREG output 520 is no longer low), the high side logic 530 outputs a high (e.g., binary 1) voltage, which turns off the PMOS transistor 510 and causes the low side logic 532 to assert a high (e.g., binary 1) signal on the gate of the transistor 512, which turns on the NMOS transistor 512. The NMOS transistor 512 then allows current to flow from ground to the node 524. In this manner, when the PMOS transistor 510 is turned on, current flow through the inductor 516 begins to increase exponentially. When the PMOS transistor 510 is turned off and the NMOS transistor 512 is turned on, the inductor 516 continues to draw current from ground inasmuch as an inductor 516 resists changes in current.

The low side logic 532 further takes as an input the output of a comparator 538. The comparator 538 has a positive input coupled to the node 524 between the transistors 510 and 512 and a negative input coupled to a low (e.g., binary 0) voltage. Accordingly, when the voltage at the node 524 is above the low voltage, the comparator 538 will output a high (e.g., binary 1) voltage at its output. The low side logic 532 may be configured to transition the output to the gate of the transistor 512 to a low (e.g., binary 0) voltage in response to the high voltage on the output of the comparator 538. Accordingly, the NMOS transistor 512 will be turned off when the PMOS transistor 510 is turned on and the node 524 rises above the low voltage.

In this example, the buck converter 312 uses a pulse frequency modulation scheme with the transistors 510 and 512 operating in a mix of sub-threshold, near-threshold and super-threshold regimes. Other modulation schemes such as pulse width modulation may be used for the buck converter as well. The resistive divider 534 has two tunable resistive elements 540 and 542. As previously stated, a first signal is used to control the divide ratio of the resistors 540 and 542 to adjust the value of VREG. The value of the first signal is typically set during IC manufacturing, but, if desired, may be changed dynamically to adapt to current operating conditions.

The buck converter 312 receives multiple control signals from the controller 320 in FIG. 3. A first signal controls the absolute value of the divide ratio of a resistive divider of the buck converter 312. A second signal controls whether the buck converter 312 is powered up or powered down.

Many of the aforementioned characteristics rely on tuning of the system 110 to minimize variations across process and temperature parameters in operation of the system 110. This requires careful calibration at the time of post-manufacturing testing. Manufacturing tests require a means to read out each important voltage, including reference voltages, internal nodes of feedback dividers, and regulated outputs. This is typically achieved by having an on-chip multiplexer (not shown) with a buffering amplifier. Manufacturing tests also employ means to store calibrated values in a non-volatile manner on chip. This storage can be achieved using flash memory, one-time programmable memory, fuses, or any other means of non-volatile data storage. Any known trimming algorithm or method may be used to set the correct calibration settings for all previously discussed trimmable elements.

There are many ways to generate a regulated voltage with a PWL characteristic. In another example, the VRef voltage remains constant across temperature, but the voltage divider is adjusted across temperature may provide a PWL characteristic for the VReg output. A voltage divider such as the voltage divider 324 is typically implemented as a resistive divider. By placing a current source with a PWL behavior in parallel with the bottom resistor, the value of VReg can also be made have a PWL characteristic.

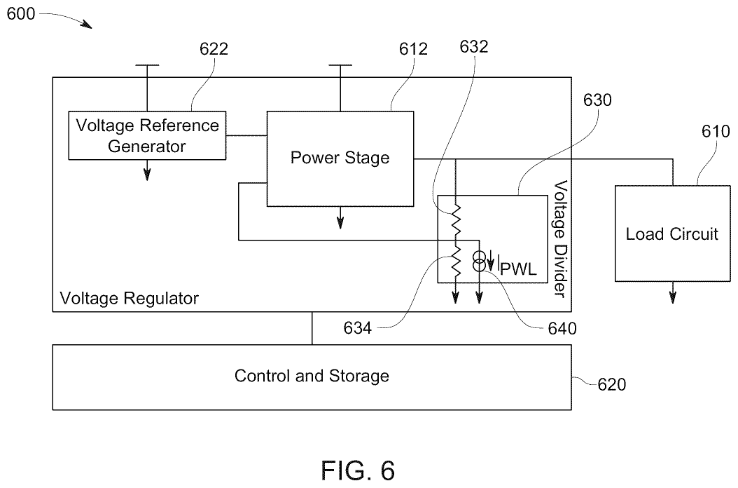

FIG. 6 is a block diagram of another example voltage converter 600 that tunes the PWL characteristic via a PWL current source. In general, the voltage converter 600 is adapted to deliver to a load 610, e.g., any of the several components in the system 110 in FIG. 2, a regulated voltage that is dynamically adjusted as a function complementary to absolute temperature. The example voltage converter 600 outputs voltage according to a piecewise linear curve. The parameters of the output voltage curve may be tuned for different requirements such as subthreshold or near subthreshold voltage levels.

The battery 150 supplies a voltage, VBat, to the example voltage converter 600, which generates a lower regulated voltage, VReg, that may be delivered to the load circuit 610, which can be a circuit of any type such as the SSRAM 272, or other components in FIG. 2. The voltage VReg may be at a sub-threshold, a near-threshold or a super-threshold level for transistors of the circuit. In this example, the voltage converter 600 may comprise a voltage output circuit that may be switching converters such as a buck converter 612 or a voltage regulator such as linear voltage regulator. A voltage controller 620 controls the value of the output voltage and also tunes the outputs.

The controller 620 controls the output of a voltage reference (VRef) generator 622 that supplies a reference voltage to the voltage output circuit 612. The regulated voltage output is fed back through a voltage divider circuit 630 to the voltage circuit 612 to regulate the voltage level.

The voltage level output by the voltage circuit 612 is controlled by changing the voltage divider circuit 630 in this example with respect to temperature and/or process. The voltage divider circuit 630 is implemented as a resistive divider between resistors 632 and 634. By placing a current source 640 with a PWL behavior in parallel with the bottom resistor 634, the value of VReg can also be made have a PWL characteristic. Any voltage divider approach can be used, including a resistive divider and diode divider. Similarly, any technique for generating a current source with PWL characteristic may be used.

Other reference current circuits that generate a reference current may also be used. It should be noted that most implementations of a reference current generator will not generate a perfect PWL characteristic. The CTAT and ZTC portions of the curve may not be perfectly linear. This is not critical. It is instead important that the curve sections have a substantially linear CTAT characteristic and a ZTC that results in a substantially flat saturation voltage. The parameters of the output voltage curve may be tuned for different requirements such as subthreshold or near subthreshold voltage levels.

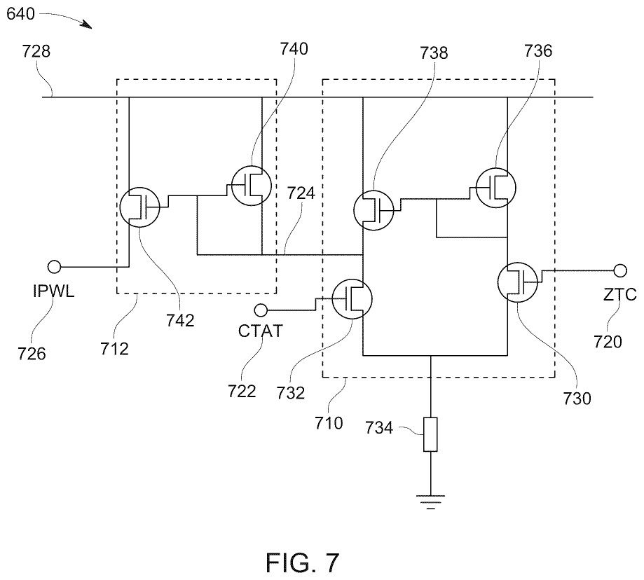

FIG. 7 is a circuit diagram of the example current source 640 in FIG. 6 that generates a piecewise-linear reference current. The current source 640 includes a first circuit stage 710 and a second circuit stage 712. Inputs to the first circuit stage 710 include a first input port 720 that is coupled to the signal for a zero-temperature coefficient voltage (ZTC) input and a second input port 722 is coupled to the signal for a complementary to absolute temperature (CTAT) input. The first circuit stage 710 generates a first stage output voltage at node 724 that is fed to the second circuit stage 712. The second circuit stage 712 uses the voltage at node 724 to generate a piecewise-linear current (IPWL) at an output port 726. A voltage rail 728 for powering the stages 710 and 712 is coupled to the battery 150 in FIG. 1.

In some implementations, the ZTC input at the first input port 720 of the first circuit stage 710 is a voltage input, and the CTAT input at the second input port 722 of the first circuit stage 710 is also a voltage input. The first circuit stage 710 controls the voltage at node 724 such that the voltage at node 724 is proportional to a difference between the voltage inputs at the first input port 720 and the second input port 722. The second circuit stage 712 is coupled to the voltage at the node 724. The second circuit stage 712 is configured to generate the piecewise-linear current at the output port 726 from the voltage at node 724.

In some implementations, the first circuit stage 710 includes a first input transistor 730 and as second input transistor 732. The gate voltage at the first input transistor 730 can be voltage of the first input port 720. The gate voltage at the second input transistor 732 can be voltage of the second input port 722. In some implementations, source terminals of the first input transistor 730 and the second input transistor 732 are coupled together. In some implementations, the coupled source terminals of the first input transistor 730 and the second input transistor 732 are coupled to a tail current component 734. The tail current component 734 can be, for example, a tail resistor (e.g., Rtail), a current source, and/or a transistor.

In some implementations, the first circuit stage 710 includes a load portion. In some implementations, the load portion is a current mirror. The current mirror can include a first load transistor 736 and a second load transistor 738. In some implementations, the current mirror is coupled to drains of both the first input transistor 730 and the second input transistor 732 such that the voltage at node 724 is the voltage at the coupled drains of the second load transistor 738 and the second input transistor 732.

In some implementations, the second circuit stage 712 includes a second current mirror. The second current mirror can include transistors 740 and 742. The voltage at node 724 can be coupled to the gates of the transistors 740 and 742. The drain of the transistor 742 can be provided as the output port 726 such that current flowing through the transistor 742 is the piecewise-linear current.

In some implementations, the circuit configuration of FIG. 7 with a resistor Rtail as the tail current component 734 provides the following relationship:

$$IPWL = \{ \begin{matrix}\frac{CTAT - ZTC}{Rtail} , & CTAT > ZTC \\ 0 , & CTAT < ZTC\end{matrix}$$

Thus, the reference current has a CTAT section below the saturation temperature defined by ZTC resulting in a regulated voltage with a CTAT association with the temperature. At temperatures above the saturation temperature, the reference current is zero resulting in a constant saturation voltage.

The piecewise linear characteristic of the regulated voltage output by the example voltage converter 300 has three key characteristics of interest: a complementary-to-absolute temperature (CTAT) slope value, a saturation voltage (VDDSAT) and a saturation temperature (TSAT). In this example, all three characteristics are tunable in production testing. The tuned values are then stored in on-chip memory structures on the system 110 such as the OTP 274. These structures may use any known memory type including registers, SRAMs, flash memory and other non-volatile memories, one-time programmable memory, and fuses.

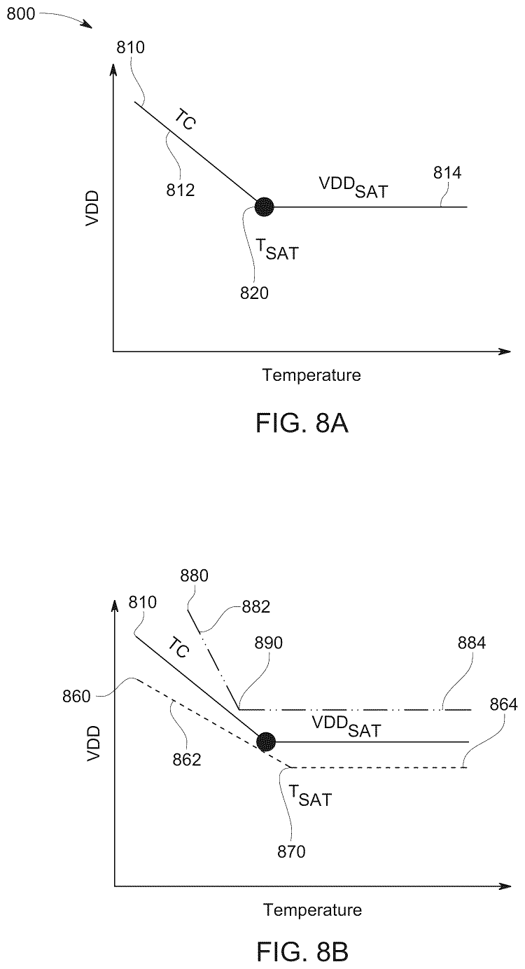

FIG. 8A is a voltage graph 800 showing the three key characteristics of interest for a piecewise linear function (PWL) voltage output of the example adaptive voltage converter 300 or the adaptive voltage converter 600. The graph 800 plots supply voltage against temperature. An output voltage curve 810 includes a linear complementary-to-absolute temperature (CTAT) section 812 and a saturated section 814. The saturation temperature is plotted as a point 820. The linear CTAT section 812 has the CTAT slope value that defines a function of voltage in relation to temperature.

In this example, the example adaptive voltage converter 300 or 600 allows adjustment for any of the three key characteristics in order to tune the output voltage supplied to power components to take into account temperature and process corners. As explained above, such tuning may be made by the controller 320 through the control signals to the reference voltage generator 322 in FIG. 3 or by the controller 620 through control signals to the voltage divider circuit 630.

The desired tuning values may be identified using a variety of techniques. For example, a process control monitor (PCM) circuit could be used to measure a process corner, which may then be used to compute an appropriate target tuning value. Alternatively, a voltage can be adjusted on a critical timing path or oscillator until switching speed matches some pre-determined target, and the resulting voltage can be used to compute an appropriate tuning value. The target tuning value may also be adjusted based on known process measurements at a wafer or lot level. Any other technique that adjusts the voltage based on measuring circuit characteristics is similarly acceptable.

The CTAT slope value is a measure of how much the regulated voltage drops for every one degree change in temperature and is usually measured in units of “volts per degree C.” The CTAT slope value may be a fixed value for all chips or may be adapted for each group of chips (e.g., from wafer to wafer or from lot to lot), or may be uniquely tuned for each chip. Any technique that adjusts the CTAT slope based on measuring circuit characteristics is acceptable. For example, a process control monitor (PCM) circuit can be used to measure a process corner, which may then be used to compute an appropriate CTAT slope.

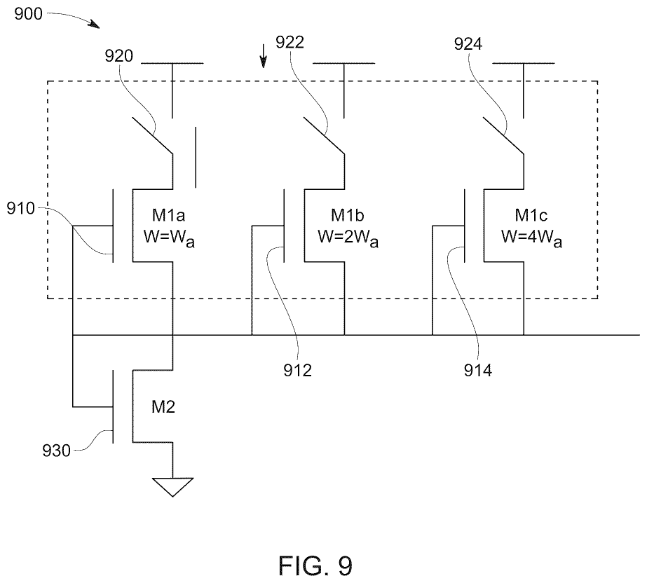

In this example, the CTAT slope can be changed by adjusting effective transistor sizing of one of the transistors in the CTAT reference voltage generator 412 in FIG. 4. FIG. 9 shows an example of a two-transistor reference voltage generator 900 that has tunable temperature coefficient. The upper transistor (e.g., transistor 738 in FIG. 7) is replaced with a series of binary weighted transistors 910, 912, or 914 that may be enabled or disabled to set either CTAT or ZTC. The binary weighted transistors 910, 912, or 914 may be activated via corresponding switches 920, 922, or 924 by a digital control signal from the controller based on the desired tuning value. In this example, the transistor 910 has the smallest width, the transistor 912 has a width that twice that of the transistor 910, and the transistor 914 has a width that is four times that of the transistor 910. Thus different values for the trim value for either ZTC or CTAT or both may be output. In this example, the sensitivity may be tuned for 7 discrete levels using the three transistors 910, 912, or 914 that may be selectively turned on from the control signal. Finer increments may be achieved by adding transistors for higher resolution such as 16 or 32 bits. The example binary weighting circuit is not the only weighting scheme that may be used. Finer increments may be achieved by adding transistors for higher resolution.

The saturation voltage and the saturation temperature are the voltage level and temperature, respectively, at which the CTAT value switches to a value of zero V/C (i.e., a zero temperature coefficient or ZTC). The saturation voltage and the saturation temperature may be fixed values for all chips, may be adaptive for each group of chips, or may be uniquely tuned for each chip. As with the CTAT slope, any technique that adjusts the saturation voltage and saturation temperature based on measuring circuit characteristics is acceptable. For example, a PCM circuit can be used to measure process corner, which may then be used to compute an appropriate saturation voltage. For example, both the saturation voltage and the saturation temperature may be adjusted by raising or lowering the value of the voltage generated by the ZTC reference voltage generator 410 in FIG. 4 or the ZTC input value 720 in the current source 640 in FIG. 7. This could be achieved by placing a variable gain amplifier with tunable gain at the output of the ZTC reference signal.

FIG. 8A shows another graph 850 that shows the results of tuning different parameters of the PWL curve 810 in FIG. 8A. An example curve 860 includes a different linear CTAT section 862 and a different saturated section 864 from those of the curve 810. In this example, the CTAT section 862 has a shallower slope than that of the CTAT section 812 of the curve 810. As explained above, the slope may be adjusted by any known tuning method including tuning the binary weighted transistor in the voltage reference generator 900 in FIG. 9. The saturation voltage represented by the saturated section 864 is lower than that of the curve 810. The saturation temperature as indicated by a point 870 is higher than the previous saturation temperature represented by point 820 in FIG. 8A. As explained above, the tuning of the saturation voltage or the saturation temperature can be achieved using any known tuning method including the tuning of a variable gain amplifier at the output of the ZTC reference voltage generator 410 in FIG. 4.

Another curve 880 includes a different linear CTAT section 882 and saturated section 864 from the curve 810. In this example, the CTAT section 882 has a steeper curve than that of the section 812 of the curve 810. The saturation voltage represented by the saturated section 884 is also higher than that of the curve 810. The saturation temperature as indicated by a point 890 is lower than the previous saturation temperature represented by point 820 in FIG. 8A.

The example adaptive voltage converter 300 with a PWL characteristic is especially useful when generating a retention voltage for an SRAM. It is common practice to run SRAM at a high voltage when reading and writing to ensure robust operation but to “droop” the voltage to a lower value (i.e., a retention voltage) during extended idle periods to enable lower leakage levels. Minimum power is generally achieved when the retention voltage is in the near-threshold or sub-threshold region. However, operating a SRAM below extremely low voltages (e.g., 0.2V or 0.3V) can result in failures, so the PWL characteristic may be used to ensure the output of a “saturation” voltage at a critical voltage value to ensure the SRAM will remain operational.

Voltage converters often provide multiple output voltages. For example, a single inductor multiple output (SIMO) buck converter takes a single voltage as input and generates two or more output voltages for use by downstream loads. Alternatively, other types of voltage converters may be multiplexed to generate different voltages. A voltage converter such as the voltage converter 300 in FIG. 3 generating two or more output voltages may implement a PWL characteristic on one of the output voltages, some of the output voltages, or all the output voltages.

Voltage converters often operate in different modes. For example, when configured in a low power mode, the example voltage converter 300 is optimized to provide low current at high efficiency from the linear regulator 314. The example voltage converter 300 is optimized to provide high current at high efficiency from the buck converter 312 for a high performance mode. A voltage converter with two or more operating modes may implement a PWL characteristic in one operating mode, some operating modes, or all operating modes.

Thus it is apparent that an adaptive voltage converter designed specifically to compensate for the exponential sensitivities of sub-threshold and near-threshold circuits has been disclosed. The example adaptive voltage converter allows adjustment of a slope of a CTAT section, a saturation temperature, and a saturation voltage of an absolute voltage section, of a piecewise linear curve defining the output voltage.

Embodiments of the present disclosure may comprise or utilize a special purpose or general-purpose computer including computer hardware, such as, for example, one or more processors and system memory, as discussed in greater detail below. Embodiments within the scope of the present disclosure also include physical and other computer-readable media for carrying or storing computer-executable instructions and/or data structures. In particular, one or more of the processes described herein may be implemented at least in part as instructions embodied in a non-transitory computer-readable medium and executable by one or more computing devices (e.g., any of the media content access devices described herein). In general, a processor (e.g., a microprocessor) receives instructions, from a non-transitory computer-readable medium, (e.g., a memory, etc.), and executes those instructions, thereby performing one or more processes, including one or more of the processes described herein.

Computer-readable media can be any available media that can be accessed by a general purpose or special purpose computer system. Computer-readable media that store computer-executable instructions are non-transitory computer-readable storage media (devices). Computer-readable media that carry computer-executable instructions are transmission media. Thus, by way of example, and not limitation, embodiments of the disclosure can comprise at least two distinctly different kinds of computer-readable media: non-transitory computer-readable storage media (devices) and transmission media.

Non-transitory computer-readable storage media (devices) includes RAM, ROM, EEPROM, CD-ROM, solid state drives (“SSDs”) (e.g., based on RAM), Flash memory, phase-change memory (“PCM”), other types of memory, other optical disk storage, magnetic disk storage or other magnetic storage devices, or any other medium which can be used to store desired program code means in the form of computer-executable instructions or data structures and which can be accessed by a general purpose or special purpose computer.

Computer-executable instructions comprise, for example, instructions and data which, when executed at a processor, cause a general purpose computer, special purpose computer, or special purpose processing device to perform a certain function or group of functions. In one or more embodiments, computer-executable instructions are executed on a general purpose computer to turn the general purpose computer into a special purpose computer implementing elements of the disclosure. The computer executable instructions may be, for example, binaries, intermediate format instructions such as assembly language, or even source code. Although the subject matter has been described in language specific to structural marketing features and/or methodological acts, it is to be understood that the subject matter defined in the appended claims is not necessarily limited to the described marketing features or acts described above. Rather, the described marketing features and acts are disclosed as example forms of implementing the claims.

The processes and logic flows described in this specification can be performed by one or more programmable processors executing one or more computer programs to perform actions by operating on input data and generating output. The processes and logic flows can also be performed by, and apparatus can also be implemented as, special purpose logic circuitry, e.g., an FPGA (field programmable gate array) or an ASIC (application-specific integrated circuit).

While various embodiments of the present invention have been described above, it should be understood that they have been presented by way of example only, and not limitation. Numerous changes to the disclosed embodiments can be made in accordance with the disclosure herein, without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations, and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

Each of these embodiments and obvious variations thereof is contemplated as falling within the spirit and scope of the claimed invention, which is set forth in the following claims.

What is claimed is:

1. An adaptive voltage converter comprising:
a voltage output circuit outputting a regulated voltage;
a voltage divider circuit coupled to the voltage output circuit; and
a voltage reference generator coupled to the voltage output circuit, wherein at least one of the voltage reference generator or the voltage divider circuit output a tuned voltage reference signal to the voltage output circuit to output the regulated voltage on a piecewise linear (PWL) curve based on tuning of at least one of a saturation temperature or a saturation voltage.

2. The voltage converter of claim 1, further comprising a voltage controller coupled to the voltage reference generator and the voltage divider circuit, the voltage controller controlling the voltage reference generator or the voltage divider to output the tuned voltage reference signal to the voltage output circuit.

3. The voltage converter of claim 2, wherein the voltage controller outputs a first tuning signal to the reference voltage generator or the voltage divider circuit to set the saturation temperature and a second tuning signal to the reference voltage generator or the voltage divider circuit to set the saturation voltage.

4. The voltage converter of claim 2, wherein the voltage controller is an integrated circuit having trim value outputs for tuning the saturation temperature and saturation voltage.

5. The voltage converter of claim 2, wherein the voltage controller is operable to control the voltage reference generator or the voltage divider circuit to tune a slope of a complementary temperature (CTAT) section of the PWL curve.

6. The voltage converter of claim 1, wherein the voltage output circuit is one of a linear regulator or a switching converter.

7. The voltage converter of claim 1, wherein the tuning incorporates a process corner of an integrated circuit.

8. The voltage converter of claim 1, wherein the voltage reference generator includes a temperature dependent adjustment circuit that adjusts the reference voltage based on temperature.

9. The voltage converter of claim 1, further comprising a temperature sensor coupled to logic to adjust a reference voltage based on sensed temperature.

10. The voltage converter of claim 1, wherein the regulated voltage is a selected one of a sub-threshold voltage less than a threshold voltage of a transistor (Vdd<Vth) of an integrated circuit and a near-threshold voltage greater than or equal to the threshold voltage of the transistor and less than or equal to 0.4 volts above the threshold of the transistor (Vth≤Vdd≤(Vth+0.4 volts)).

11. The voltage converter of claim 1, wherein the voltage reference generator includes a circuit to tune the saturation temperature and the saturation voltage.

12. The voltage converter of claim 1, wherein the voltage divider circuit includes a piecewise linear current source.

13. A method of tuning an adaptive voltage converter including a voltage output circuit outputting a voltage according to a piecewise linear regulated voltage curve having a complementary-to-absolute-temperature section and a saturation voltage section, the method comprising:
determining a saturation voltage of the piecewise linear regulated voltage curve;
determining a saturation temperature for the piecewise linear regulated voltage curve; and
tuning at least one of a voltage reference generator or a voltage divider to output a reference voltage to a voltage output circuit according to one of the determined saturation voltage or saturation temperature.

14. The method of tuning in claim 13, wherein a voltage controller coupled to the voltage reference generator and the voltage divider circuit controls the voltage reference generator or the voltage divider to output the tuned voltage reference signal to the voltage output circuit.

15. The method of claim 14, wherein the voltage controller is an integrated circuit having trim value outputs for tuning the saturation temperature and saturation voltage.

16. The method of claim 13, further comprising controlling the voltage reference generator or the voltage divider circuit to tune a slope of a complementary temperature (CTAT) section of the PWL curve.

17. The method of claim 13 wherein the tuning incorporates a process corner of an integrated circuit.

18. The method of claim 13, wherein the voltage reference generator includes a temperature dependent adjustment circuit that adjusts the reference voltage based on temperature.

19. The method of claim 13, wherein the regulated voltage is a selected one of a sub-threshold voltage less than a threshold voltage of a transistor (Vdd<Vth) of an integrated circuit and a near-threshold voltage greater than or equal to the threshold voltage of the transistor and less than or equal to 0.4 volts above the threshold of the transistor (Vth≤Vdd≤(Vth+0.4 volts)).

20. A non-transitory computer readable medium including executable instructions which, when executed in a processor, causes the processor to:
determine a saturation voltage of a piecewise linear regulated voltage curve having a complementary-to-absolute-temperature section and a saturation voltage section;
determine a saturation temperature for the piecewise linear regulated voltage curve; and
tune at least one of a voltage reference generator or a voltage divider to output a reference voltage to a voltage output circuit according to one of the determined saturation voltage or saturation temperature.
